(19) United States
(12) Patent Application Publication
(10) Pub. No.: US 2009/0294918 A1
(43) Pub. Date: Dec. 3, 2009

(54) SEMICONDUCTOR WAFER

(75) Inventors: Takeo KATOH, Tokyo (JP); Kazushige TAKAISHI, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/475,769

(22) Filed: Jun. 1, 2009

(30) Foreign Application Priority Data
Jun. 3, 2008 (JP) 2008-146228

(51) Int. Cl. H01L 23/28

(52) U.S. Cl. 257/629; 257/E23.194; 257/E23.116

(57) ABSTRACT

In a state where a semiconductor wafer is not acted upon by its own weight, a shear stress on a rear surface side portion of the semiconductor wafer is higher than that on a front surface side portion of the semiconductor wafer, in a compression direction. Thereby, sag of the semiconductor wafer is reduced when the semiconductor wafer is simple-supported in a horizontal state.

### CROSS-REFERENCE TO RELATED APPLICATIONS

The present application claims priority under 35 U.S.C. §119 of Japanese Application No. 2008-146228 filed on Jun. 3, 2008, the disclosure of which is expressly incorporated by reference herein in its entirety.

### BACKGROUND OF THE INVENTION

1. Field of the Invention

The present invention relates to a semiconductor wafer, and more specifically, relates to a semiconductor wafer that is harder to sag than a conventional wafer when it is simple-supported in a horizontal state.

2. Description of Related Art

For example, in a device process, during exposure, light from an exposure source is irradiated on a pattern formed on a mask (reticle) through a stepper (reduced-projection type exposure device), for example, and the light passing through the pattern is reduced by a reduced-projection lens before being transferred onto a surface of a silicon wafer (semiconductor wafer) coated with a photoresist (see, for example, Japanese Patent Laid-open Publication No. 2005-228978). As shown in FIG. 3, a silicon wafer 100 shipped out of a wafer manufacturing facility is a CZ (Czochralski type) wafer having a diameter of 300 mm, a thickness of 775 μm, a solid solution oxygen concentration of from 5×10¹⁷ to 11×10¹⁷ atoms/cm³, and a Young's modulus of 110 GPa. During exposure, the silicon wafer 100 is simple-supported from below at 6 points of its periphery by 6 support pins 101 arranged on a wafer stage along a circumferential direction of the stage (circumferential direction of the wafer) at every 60°, the stage being disposed at a bottom part of a stepper.

As described above, the conventional silicon wafer 100 is a CZ wafer having a solid solution oxygen concentration of from 5×10⁷ to 11×10¹⁷ atoms/cm³ and a Young's modulus of 110 GPa, for which a sufficient countermeasure against sag has not yet been implemented. Therefore, in the case of a next generation silicon wafer having a large diameter of 450 mm or more, for example, when a silicon wafer is simple-supported at its periphery on the wafer stage of the stepper or in a cassette box and the like, large sag occurs to the horizontally disposed silicon wafer 100 (dashed-two-dotted lines in FIG. 3) under the wafer's own weight (solid lines in FIG. 3). For example, in case of transporting the wafers in a cassette box, the sag has to be taken into consideration in arranging support intervals for the wafers in a cassette box, consequently widening the support intervals. In other words, the number of the wafers contained in a cassette box is reduced. Alternatively, the size of a cassette box needs to be increased.

### SUMMARY OF THE INVENTION

As a result of an extensive research, the inventors focused on a shear stress on a silicon wafer acting in a direction vertical to a thickness of the silicon wafer when an external force acts in a direction of the thickness of the silicon wafer. More specifically, the inventors focused on a shear stress exerted on a front surface side portion and a rear surface side portion of the silicon wafer. In other words, the inventors discovered that, in a state where the silicon wafer is not acted upon by its own weight and when a shear stress on the rear surface side portion of the silicon wafer is higher than that on the front surface side portion of the silicon wafer, in a compression direction (in a direction orthogonal to the thickness of the silicon wafer; in a direction in which a radius is reduced on a surface parallel to a front surface of the silicon wafer), the silicon wafer is harder to sag than a conventional wafer throughout which a shear stress (a shear stress acting in a direction orthogonal to the thickness of the silicon wafer) is uniform (across a front surface side portion and a rear surface side portion). Thereby, a non-limiting feature of the present invention was completed.

A non-limiting advantage of the present invention is to provide a semiconductor wafer that is harder to sag than a semiconductor wafer throughout which a shear stress is uniform.

A first aspect of the present invention provides a semiconductor wafer in which, in a state where a semiconductor wafer is not acted upon by its own weight, a shear stress generated on a rear surface side portion of the semiconductor wafer is higher than that generated on a front surface side portion of the semiconductor wafer, in a compression direction, so that sag is reduced when the semiconductor wafer is simple-supported in a horizontal state in which the semiconductor wafer is acted upon by its own weight.

According to the first aspect of the present invention, when the semiconductor wafer is simple-supported in a horizontal state in which the semiconductor wafer is acted upon by its own weight, the shear stress on the rear surface side portion of the semiconductor wafer is higher in a compression direction, compared to a conventional semiconductor wafer in which a shear stress is uniform across a rear surface side portion and a front surface side portion. Thereby, the semiconductor wafer is harder to sag than the semiconductor wafer throughout which the shear stress is uniform. Therefore, for example, an amount accommodating the sag of the wafer is reduced in arranging support intervals for the semiconductor wafers in a cassette box for transporting wafers. The shear stress in the compression direction refers to a shear stress component, which acts toward a center of the semiconductor wafer, of the shear stress acting on a surface parallel to a front surface and a rear surface of the semiconductor wafer. Alternatively, the shear stress in the compression direction refers to a shear stress acting in a direction orthogonal to a thickness of the semiconductor wafer in which a radius of the semiconductor wafer is reduced. The shear stress on the front surface side portion of the semiconductor wafer may be higher than that on the conventional semiconductor wafer, in the compression direction. However, this method is not preferable, as sag of the semiconductor wafer is greater than that of the conventional semiconductor wafer when the semiconductor wafer is supported in a horizontal state with its front surface up.

As the semiconductor water, a monocrystalline silicon wafer and a multicrystalline silicon wafer, and the like may be employed. The front surface of the semiconductor wafer is mirror-finished. A diameter of the semiconductor wafer is, for example, 200 mm, 300 mm, 450 mm, or the like. “The semiconductor wafer is simple-supported in a horizontal state” refers to a condition in which the semiconductor wafer that is horizontally disposed is supported in an unfixed state in which the semiconductor wafer is acted upon only by its own weight.

“A front surface side portion of the semiconductor wafer” refers to, in a cross-section orthogonal to the front and rear surfaces of the semiconductor wafer, a portion of the semiconductor wafer at the front surface side based on a base surface including a virtual line extending in a diametrical direction of the semiconductor wafer at half the thickness (height) of the semiconductor wafer. The front surface of the semiconductor wafer is a mirror-finished surface on which a device is formed.

“A rear surface side portion of the semiconductor wafer” refers to a portion of the semiconductor wafer at the rear surface side based on the base surface including the virtual line. “A shear stress on a rear surface side portion of the semiconductor wafer is higher than that on a front surface side portion of the semiconductor wafer, in a compression direction” refers to a condition in which, when an external force acts in front and rear directions, a component (shear stress), which acts toward a center of the semiconductor wafer, of resistance acting in a direction parallel to the base surface is larger on the rear surface side of the semiconductor wafer than on the front surface side of the semiconductor wafer. It is desirable that a value obtained by dividing a difference between a compression-shear stress on the rear surface side portion of the semiconductor wafer (a stress component acting toward the central direction of a wafer surface) and a compression-shear stress on the front surface side portion of the semiconductor wafer by a average value of the compression-shear stress on the rear surface side portion of the semiconductor wafer and the compression-shear stress on the front side surface portion of the semiconductor wafer be 10-1000%. When the value is less than 10%, effectiveness in reducing the sag is reduced. When the value exceeds 1000%, the sag of the semiconductor wafer itself increases, making handling of the semiconductor wafer difficult.

Examples of manufacturing methods of such semiconductor wafers include a method in which a semiconductor monocrystal pulled up according to the Czochralski method sequentially undergoes grinding of an outer periphery, cutting in blocks, and slicing. Then, each process of chamfering, lapping, etching, and polishing are sequentially applied. Subsequently, a high stress film, which has a smaller lattice constant than that of a material of the semiconductor wafer, is formed on a rear surface of an obtained semiconductor wafer. Alternatively, a shrinkable-resin based matter may be applied. Thereby, the semiconductor wafer is provided.

A second aspect of the present invention provides the semiconductor wafer, in which a high stress film, which has a smaller lattice constant than that of a material of the semiconductor wafer, is formed on a rear surface of the semiconductor wafer.

According to the second aspect of the present invention, in general, the smaller a lattice constant and a crystal grain size are in metal composition, the larger a slip resistance (deformation resistance of metal) of crystals abutting each other at a grain boundary therebetween. In addition, the strength of a grain boundary itself is slightly greater than that of a crystal itself, in general. Therefore, the larger the number of grain boundaries is (i.e., the smaller a lattice constant and a crystal grain size are in metal composition), the larger the deformation resistance of metal. Thereby, a metal material is rendered hard to sag. Applying the above, the high stress film, which has a smaller lattice constant than that of the material of the semiconductor wafer, is formed on the rear surface of the semiconductor wafer. Thereby, the shear stress (the shear stress acting radially toward the center) is higher on the rear side surface portion of the semiconductor wafer than on the front side surface portion of the semiconductor wafer. As a result, the semiconductor wafer is rendered harder to sag than a conventional semiconductor wafer throughout which a shear stress is uniform.

It is desirable that a difference between the lattice constant of the material of the semiconductor wafer and the lattice constant of the high stress film be 0.01-1%. When the difference is less than 0.01%, a stress generated in an interface (an in-plane stress acting in the compression direction) is low, and therefore effectiveness in reducing the sag cannot be expected. When the difference exceeds 1%, an epitaxial condition cannot be maintained, and therefore a stress is not generated. Herein, the high stress film refers to a film having a smaller lattice constant than that of the material of the semiconductor wafer and having a larger deformation resistance than that of the material of the semiconductor wafer. Specifically, a silicon compound in which a chemical element with a smaller atomic radius than that of a silicon is introduced at a substitution site may be employed as the high stress film. Alternatively, the high stress film may be a resist film.

The resist film may be a negative resist film which is rendered insoluble in a developer in a portion exposed to photoirradiation or a positive resist film which is rendered soluble in a developer in a portion exposed to photoirradiation. For the negative resist film, an organic solution containing as a solute a mixture of a cyclized polyisoprene and a photosensitive material that causes a crosslinking reaction may be employed. For the positive resist film, a matter obtained by adding a quinonediazide compound as a photosensitizing agent to a resin based on a novolak resin and then by adding a solvent, such as a cellosolve, a xylene, and the like, may be employed. It is desirable that the resist film have a thickness of 0.1-10 μm. When the thickness is less than 0.1 μm, effectiveness in generating the stress is weak. When the thickness exceeds 10 μm, effectiveness obtained by an increased thickness is reduced, causing a manufacturing cost problem.

The high stress film has a thickness of 0.1-10 μm. When the thickness is less than 0.1 μm, effectiveness in generating the stress is weak. When the thickness exceeds 10 μm, effectiveness obtained by an increased thickness is reduced, causing a problem of increased manufacturing costs.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 is a cross-sectional view showing a semiconductor wafer according to a first embodiment of the present invention before it is supported;

FIG. 2 is a cross-sectional view showing the semiconductor wafer according to the first embodiment of the present invention when it is point-supported; and

FIG. 3 is a cross-sectional view showing a semiconductor wafer according to a conventional method before it is supported and when it is supported.

### DETAILED DESCRIPTION OF THE INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description is taken with the drawings making apparent to those skilled in the art how the forms of the present invention may be embodied in practice.

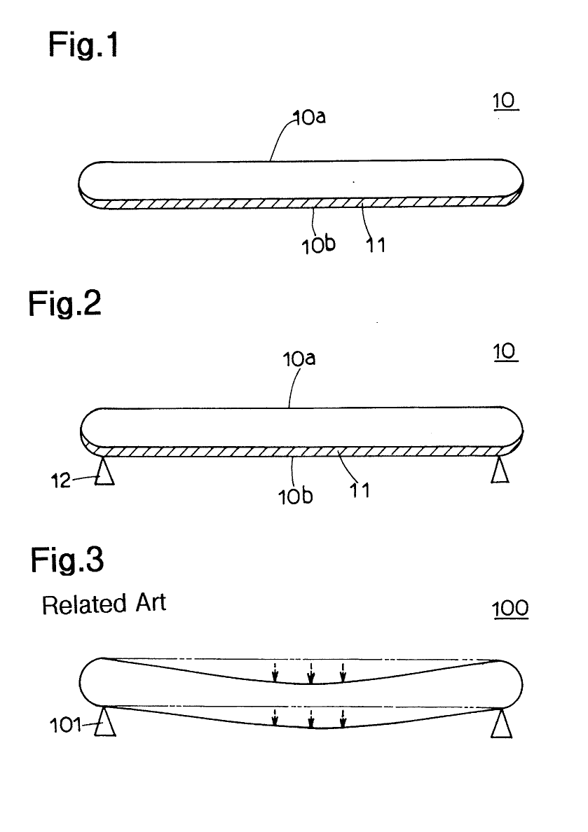

Hereinafter, the embodiment of the present invention is explained in detail. FIG. 1 shows a silicon wafer 10 according to a first embodiment of the present invention. When the silicon wafer 10 is simple-supported in a horizontal state in the atmosphere, a shear stress on a rear surface side portion 10b of the silicon wafer 10 is higher than that on a front surface side portion 10a of the silicon wafer 10, in a compression direction (radially toward a center of the wafer). Specifically, a silicon-boron film (high stress film) 11, which has a smaller lattice constant (5.35 A) than a lattice constant (5.43 A) of the silicon wafer 10, is formed on a rear surface of the silicon wafer 10. Herein, A stands for angstrom.

Hereinafter, the silicon wafer 10 is explained in detail. The silicon wafer is a mirror-finished positive monocrystal CZ (Czochralski type) wafer having a diameter of 450 mm, a thickness of 775 μm, a specific resistance of 10 Ω·cm, a solid solution oxygen concentration of 8×10¹⁷ atoms/cm³, and a Young's modulus of 110 GPa. In manufacturing the silicon wafer 10, a silicon monocrystal pulled up from a melt in a crucible according to the Czochralski method sequentially undergoes grinding of an outer periphery, cutting in blocks, and slicing, thereby a wafer is obtained. Then, the wafer sequentially undergoes each process of chamfering, lapping, etching, and polishing, thereby the silicon wafer 10 is provided.

The silicon-boron film 11 is formed across the rear surface of the silicon wafer 10 at a uniform thickness of 1 μm. Accordingly, the shear stress on the front surface side portion 10a of the silicon wafer 10 is the same as that on a monocrystalline silicon wafer. Meanwhile, the silicon-boron film 11 formed on the rear surface of the silicon wafer 10 increases the shear stress on the rear surface side portion 10b of the silicon wafer 10 to the compression side (in a central direction on the rear surface).

The manufactured silicon wafer 10 is transferred to a device process, in which a device is formed on the front surface of the silicon wafer 10. During exposure in the device formation, the silicon wafer 10 is simple-supported from below at its outer periphery by 6 support pins 12 arranged at every 60°, along a circumferential direction of a stage (in a circumferential direction of the wafer), on the wafer stage disposed at a lower portion of a stepper (FIG. 2). Light irradiated from an exposure source passes through a pattern formed on a mask, and is reduced by a reduced-projection lens. Subsequently, the light is irradiated on the front surface of the silicon wafer 10 coated with a photoresist, and thereby the pattern is transferred onto the front surface.

The silicon wafer 10 shipped out of a wafer manufacturing facility is a CZ (Czochralski type) wafer having a diameter of 450 mm, a thickness of 775 μm, a solid solution oxygen concentration of 8×10¹⁷ atoms/cm³, and a Young's modulus of 110 GPa. As described above, when the silicon wafer 10 is simple-supported in a horizontal state in which the silicon wafer 10 is not acted upon by its own weight (e.g., in a vacuum), the shear stress on the rear surface side portion 10b of the silicon wafer 10 is higher than the shear stress on the front surface side portion 10a of the silicon wafer 10, in the compression direction (in the central direction on the rear surface). Therefore, for example, when the silicon wafer 10 is simple-supported at its outer periphery on the wafer stage of the stepper, the silicon wafer 10 is harder to sag than a conventional wafer throughout which a shear stress is uniform. In addition, in arranging support intervals for the silicon wafers, for example, in a cassette box for transporting wafers in which the silicon wafers are simple-supported only at their outer peripheries, an amount accommodating the sag of the silicon wafer (an amount taken into consideration) is reduced.

In general, the smaller a lattice constant and a crystal grain size are in composition, the larger a slip resistance (deformation resistance of metal) of crystals abutting each other at a grain boundary therebetween. In addition, the strength of a grain boundary itself is slightly greater than that of a crystal itself, in general. Therefore, the larger the number of grain boundaries is (i.e., the smaller a lattice constant and a crystal grain size are in composition), the larger a deformation resistance of metal. Thereby, a material is rendered hard to sag. As described above, the silicon-boron film 11, which has a smaller lattice constant than that of a monocrystalline silicon, is formed on the rear surface of the silicon wafer 10, and therefore the silicon wafer 10 is hard to sag (i.e., sagging of the silicon wafer is reduced).

It is noted that the foregoing examples have been provided merely for the purpose of explanation and are in no way to be construed as limiting of the present invention. While the present invention has been described with reference to exemplary embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular structures, materials and embodiments, the present invention is not intended to be limited to the particulars disclosed herein; rather, the present invention extends to all functionally equivalent structures, methods and uses, such as are within the scope of the appended claims.

The present invention is not limited to the above described embodiments, and various variations and modifications may be possible without departing from the scope of the present invention.

What is claimed is:

1. A semiconductor wafer, wherein in a state where a semiconductor wafer is not acted upon by its own weight, a shear stress generated on a rear surface side portion of the semiconductor wafer is higher than that generated on a front surface side portion of the semiconductor wafer, in a compression direction, such that sag is reduced when the semiconductor wafer is simple-supported in a horizontal state in which the semiconductor wafer is acted upon by its own weight.

2. The semiconductor wafer according to claim 1, wherein a high stress film having a smaller lattice constant than that of a material of the semiconductor wafer is formed on a rear surface of the semiconductor wafer.
